(19) United States
(12) Patent Application Publication
(10) Pub. No.: US 2012/0256622 A1
(43) Pub. Date: Oct. 11, 2012

(54) HALL SENSOR HAVING OFFSET REMOVAL FUNCTION AND OFFSET REMOVING METHOD THEREOF

(75) Inventors: Sung Tae KIM, Incheon (KR); Sang Gyu Park, Anyang (KR); Kyung Uk Kim, Seoul (KR); Dong Ok Han, Suwon (KR); Seung Chul Pyo, Suwon (KR); Soo Woong Lee, Seoul (KR)

(73) Assignee: SAMSUNG ELECTRO-MECHANICS CO.,LTD.

(21) Appl. No.: 13/188,247

(22) Filed: Jul. 21, 2011

(30) Foreign Application Priority Data
Apr. 6, 2011 (KR) 10-2011-0031815

(51) Int. Cl. G01R 33/07

(52) U.S. Cl. 324/251

(57) ABSTRACT

There are provided a hall sensor having an offset removal function removing an offset included in a hall voltage, and an offset removing method thereof. The hall sensor includes: a converting unit converting first and second detection voltages detected for each of a plurality of preset detection directions by a hall device detecting a magnetic field as a voltage according to the plurality of preset detection directions into a pulse having a level difference therebetween as a width; a sign determining unit comparing the first and second detection voltages with each other and determining whether the pulse has a positive sign or a negative sign according to the comparison result; a counter counting the width of the pulse from the converting unit with a preset reference time unit; and an operating unit removing an offset voltage included in the first and second detection voltages by performing a minus operation with the numbers counted by the counter according to the sign determined by the sign determining unit.

### CROSS-REFERENCE TO RELATED APPLICATIONS

This application claims the priority of Korean Patent Application No. 10-2011-0031815 filed on Apr. 6, 2011, in the Korean Intellectual Property Office, the disclosure of which is incorporated herein by reference.

### BACKGROUND OF THE INVENTION

1. Field of the Invention

The present invention relates to a hall sensor having an offset removal function removing an offset included in a hall voltage and an offset removing method thereof.

2. Description of the Related Art

Generally, a hall sensor, which is a semiconductor device performing detection and measurement of a magnetic field using a hall effect, has been used in various applications including industrial applications and customer service applications.

In this hall sensor, an analog scheme using an amplifier has been mainly used due to a rapid response speed and excellent accuracy. However, the analog scheme has a large circuit area and high power consumption as compared to a digital scheme.

In accordance with the customer desire for slim and light products having reduced power consumption, the digital scheme has been gradually introduced into use. However, the digital scheme has shortcomings in which an offset is included in an output signal due to a change in a processing condition.

### SUMMARY OF THE INVENTION

An aspect of the present invention provides a hall sensor having an offset removal function removing an offset included in a hall voltage by converting respective hall voltages detected for each preset detection direction into pulses, counting each of the converted pulses, and then performing a minus operation on the counted numbers, and an offset removing method thereof.

According to an aspect of the present invention, there is provided a hall sensor having an offset removal function, including: a converting unit converting first and second detection voltages detected for each of a plurality of preset detection directions by a hall device detecting a magnetic field as a voltage according to the plurality of preset detection directions into a pulse having a level difference therebetween as a width; a sign determining unit comparing the first and second detection voltages with each other and determining whether the pulse has a positive sign or a negative sign according to the comparison result; a counter counting the width of the pulse from the converting unit with a preset reference time unit; and an operating unit removing an offset voltage included in the first and second detection voltages by performing a minus operation with the numbers counted by the counter according to the sign determined by the sign determining unit.

The converting unit may include: first and second inverters connected between a driving power supply terminal and a ground to thereby perform respective inverting operations according to a preset reference clock signal; a first transistor connected between the first inverter and the ground to thereby receive the first detection voltage through a gate thereof; a second transistor connected between the second inverter and the ground to thereby receive the second detection voltage through a gate thereof; and a logical gate performing an exclusive OR operation on outputs of the first and second transistors.

The converting unit may further include: a first buffer buffering the output of the first transistor and transferring the buffered output to the logical gate; and a second buffer buffering the output of the second transistor and transferring the buffered output to the logical gate.

The converting unit may further include an output buffer buffering an output of the logical gate.

The sign determining unit may determine the positive sign or the negative sign of the pulse by comparing the output of the first transistor with the output of the second transistor.

The sign determining unit may include: a first NOT gate inverting the output of the second transistor; a first AND gate performing a logical product operation on the output of the first transistor and the output of the second transistor inverted from the first NOT gate; a second NOT gate inverting the output of the first transistor; and a second AND gate performing the logical product operation on the output of the first transistor inverted from the second NOT gate and the output of the second transistor.

The operating unit may include: a first storing unit storing the number corresponding to the first detection voltage from the counter therein; a second storing unit storing the number corresponding to the second detection voltage from the counter therein; and a subtracting unit performing a minus operation on the numbers stored in the first and second storing units.

The counter may count the width of the pulse in the reference time unit in a time to digital converter scheme.

The detection directions may be a vertical direction and a horizontal direction with regard to a hall plate of the hall device.

The operating unit may perform a minus operation on the number of pulses counted when the detection direction is the vertical direction and the number of pulses counted when the detection direction is the horizontal direction.

According to another aspect of the present invention, there is provided an offset removing method of a hall sensor, including: converting first and second detection voltages detected for each of a plurality of preset detection directions by a hall device detecting a magnetic field as a voltage according to the plurality of preset detection directions into a pulse having a level difference therebetween as a width; comparing the first and second detection voltages with each other and determining whether the pulse has a positive sign or a negative sign according to the comparison result; counting the width of the pulse with a preset reference time unit; and removing an offset voltage included in the first and second detection voltages by performing a minus operation on the counted numbers according to the determined sign.

The converting of the detection voltages into the pulse may include: inverting the first and second detection voltages according to a preset reference clock signal; and performing an exclusive OR operation on the inverted voltages.

The converting may further include buffering the inverted voltages before performing the exclusive OR operation on the inverted voltages.

The converting may further include buffering a result of the exclusive OR operation.

The determining of the pulse sign may include determining whether the pulse has the positive sign or the negative sign by comparing the inverted voltages with each other.

The determining may include: inverting the inverted voltages respectively; performing a logical product operation on the inverted voltage of the first detection voltage and the inverted voltage of the inverted voltage of the second detection voltage; and performing a logical product operation on the inverted voltage of the second detection voltage and the inverted voltage of the inverted voltage of the first detection voltage.

The removing of the offset voltage may include: storing the counted numbers corresponding to the first and second detection voltages; and performing a minus operation on the counted numbers corresponding to the stored first and second detection voltages.

The counting may include counting the width of the pulse in the reference time unit in a time to digital converter scheme.

The detection directions may be a vertical direction and a horizontal direction with regard to a hall plate of the hall device.

The counting may include performing a minus operation on the number of pulses counted when the detection direction is the vertical direction and the number of pulses counted when the detection direction is the horizontal direction.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of a hall sensor according to an embodiment of the present invention;

FIGS. 2A and 2B are equivalent circuit diagrams of a hall plate used in a hall device;

FIG. 3 is a schematic configuration diagram of a hall device;

FIG. 4 is voltage graphs of main portions of the hall device shown in FIG. 3;

FIG. 5 is a schematic configuration diagram of a converting unit used in a hall sensor according to an embodiment of the present invention;

FIG. 6 is signal waveform graphs showing an operation of the converting unit shown in FIG. 5;

FIG. 7 is a schematic configuration diagram of a sign determining unit used in a hall sensor according to an embodiment of the present invention; and

FIG. 8 is signal waveform graphs of main components of a converting unit according to an embodiment of the present invention.

### DETAILED DESCRIPTION OF THE INVENTION

Embodiments of the present invention will now be described in detail with reference to the accompanying drawings such that they could be easily practiced by those having skill in the art to which the present invention pertains. However, in describing the embodiments of the present invention, detailed descriptions of well-known functions or constructions will be omitted so as not to obscure the description of the present invention with unnecessary detail.

In addition, like reference numerals denote like elements throughout the drawings.

Unless explicitly described to the contrary, the word “comprise” and variations such as “comprises” or “comprising,” will be understood to imply the inclusion of stated elements but not the exclusion of other elements.

Embodiments of the present invention will now be described in detail with reference to the accompanying drawings.

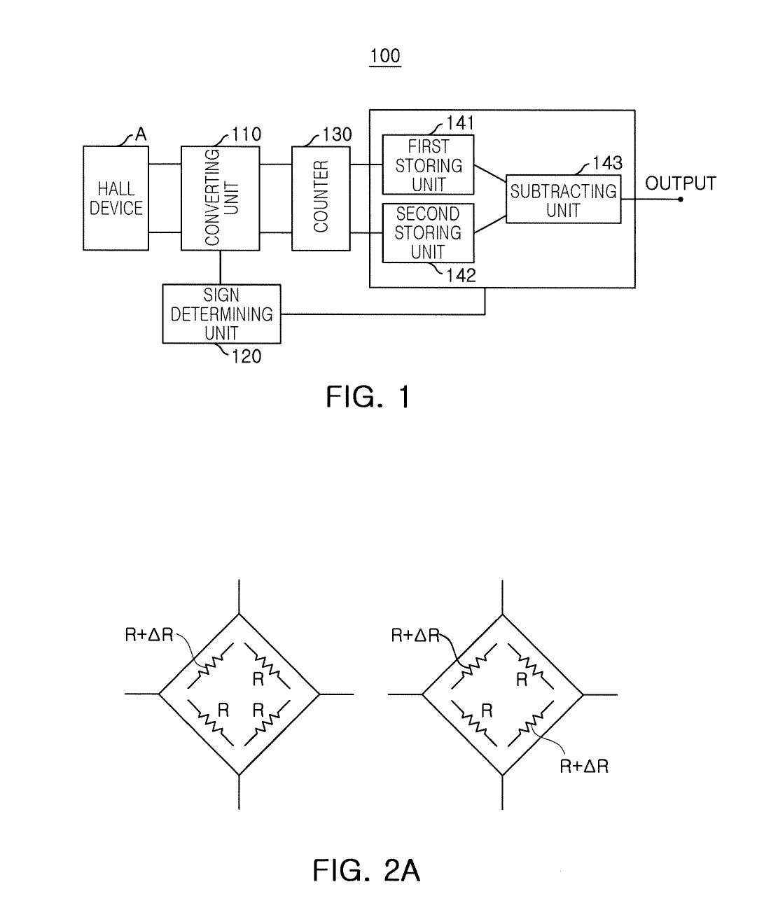

FIG. 1 is a schematic block diagram of a hall sensor according to an embodiment of the present invention.

Referring to FIG. 1, a hall sensor 100 according to an embodiment of the present invention may include a converting unit 110, a sign determining unit 120, a counter 130, and an operating unit 140.

The converting unit 110 may convert first and second detection voltages for each detection direction from a hall device A detecting magnetic fields in a plurality of preset detection directions into a pulse having a width according to a voltage level difference between the first and second detection voltages.

The sign determining unit 120 may determine a positive (+) sign or a negative (−) sign of the converted pulse by comparing the voltage levels of the first and second detection voltages with each other. For example, it may determine that the converted pulse has a positive sign when the first detection voltage is higher than the second detection voltage and determine that the converted pulse has a negative sign when the second detection voltage is higher than the first detection voltage.

The counter 130 may count the width of the pulse converted by the converting unit 110 with a preset reference time unit. To this end, the counter 130 may count the width of the pulse in a time to digital converter scheme.

The operating unit 140 may remove an offset voltage included in the first and second detection voltages by performing a minus operation on numbers counted for each of the plurality of detection directions.

To this end, the operating unit 140 may include first and second storing units 141 and 142 and a subtracting unit 143.

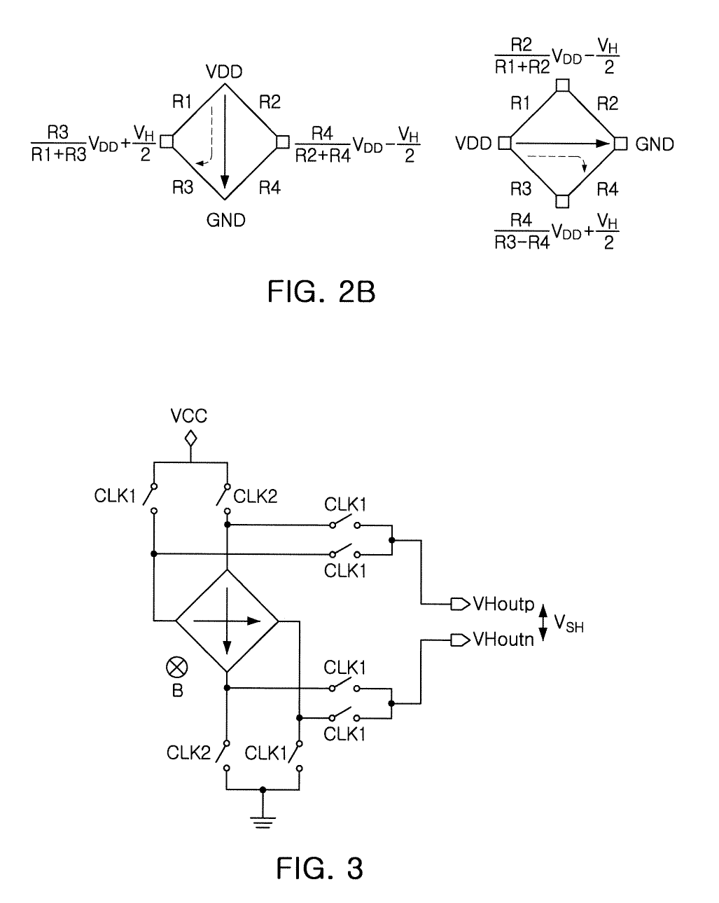

FIGS. 2A and 2B are equivalent circuit diagrams of a hall plate used in a hall device.

A hall plate used in the hall device A may have an equivalent circuit in a Wheatstone bridge form as shown in FIG. 2A. Resistance values (R) of equivalent resistors on four sides may ideally be the same. However, a resistance value R+ΔR of a resistor on one side or resistance values R+ΔR of resistors on one side and a side facing one side may be different from those of resistors of other sides due to mismatch in a semiconductor process, stress on a package forming the hall plate, or the like. Therefore, an offset voltage may be included in a detection voltage detected by the hall device A.

Referring to FIG. 2B, the hall device A may apply a current in vertical and horizontal directions with regard to the hall plate in order to detect a magnetic field and recognize a voltage generated at the time of the application of the current as a detection voltage at which the magnetic field is detected. As described above, when the resistance value R+ΔR of the resistor on one side or the resistance values R+ΔR of the resistors on one side and the side facing one side is/are different from those of the resistors of other sides, the offset voltage may be included in the detection voltage as represented by the following equation.

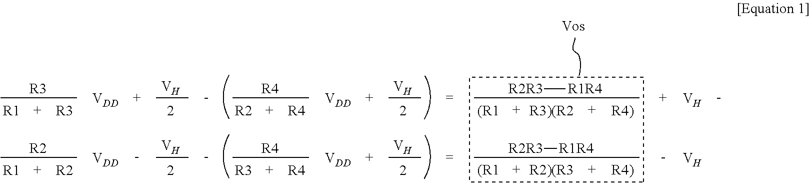

Here, V_{H} indicates a detection voltage detected by a hall effect, and V_{OS} indicates an offset voltage.

∴(R2=R3=R4),(R1=R4 AND (R2=R3)=2V_{H} [Equation 2]

That is, as represented by the above-mentioned Equations 1 and 2, when a minus operation is performed on a detection voltage in a horizontal direction from a detection voltage in a vertical direction for detecting the above-mentioned magnetic field, the offset voltage component is removed and only a voltage twice larger than the hall voltage remains, whereby the offset voltage may be removed in the detection voltage.

The hall sensor according to the embodiment of the present invention may be configured to have the structure shown in FIG. 1 in order to use the above-mentioned principle.

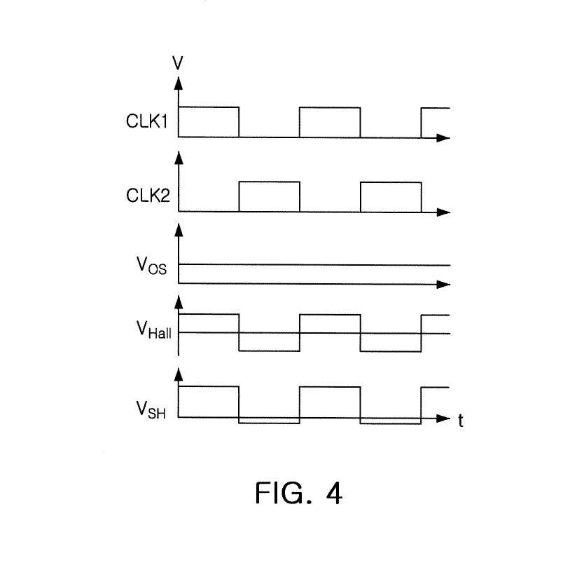

FIG. 3 is a schematic configuration diagram of a hall device, and FIG. 4 is voltage graphs of main portions of the hall device shown in FIG. 3.

Referring to FIG. 3, the hall device A may apply a current to the hall plate in vertical and horizontal directions and include a plurality of switches in order to detect a magnetic field B as a voltage at the time of the application of the current. Each of the switches may perform open and short operations according to a first clock CLK1 and a second clock CLK2 having a level inverted from that of the first clock CLK1. First and second detection voltages V_{Houtp} and V_{Houtn} are output according to the switching according to the first and second clocks CLK1 and CLK2. At this time, an offset voltage V_{OS} may be generated due to mismatch in a semiconductor process, stress of a package forming the hall plate, or the like, as described above. The above-mentioned offset voltage V_{OS} may be expressed as a direct current voltage, and be applied to a pure hall voltage Vₕₐₗₗ which is a voltage difference between the first and second detection voltages V_{Houtp} and V_{Houtn}, such that a hall voltage V_{SH} may include the offset voltage as shown in a graph of FIG. 4.

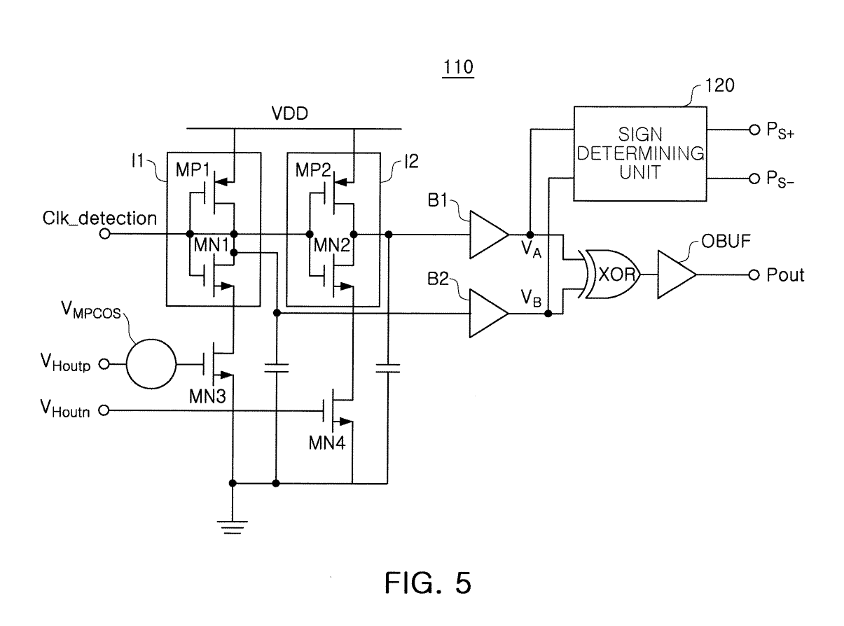

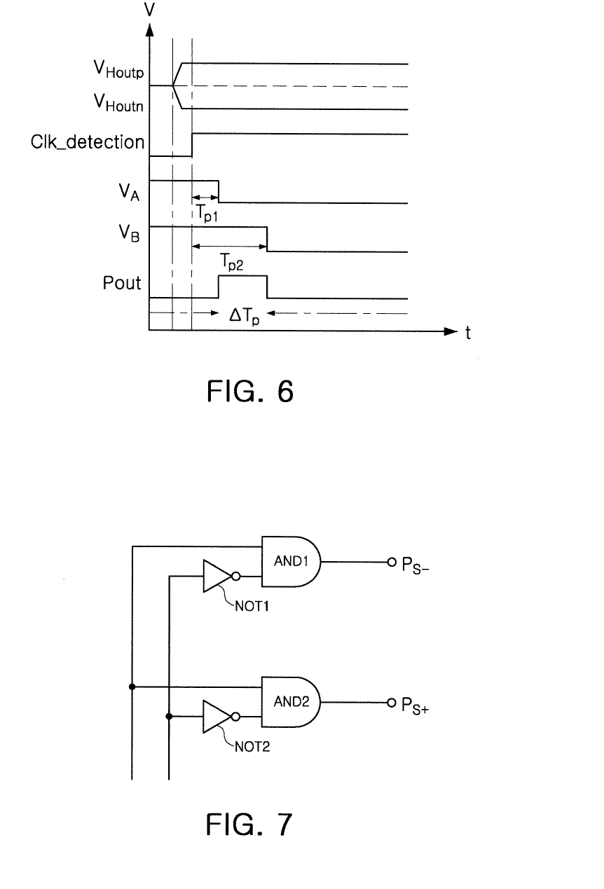

FIG. 5 is a schematic configuration diagram of a converting unit used in a hall sensor according to an embodiment of the present invention, and FIG. 6 is signal waveform graphs showing an operation of the converting unit shown in FIG. 5.

Referring FIGS. 5 and 6, a converting unit 110 used in a hall sensor according to an embodiment of the present invention may be configured of at least two inverters I1 and I2 and at least two n-channel metal oxide semiconductor (NMOS) transistors MN3 and MN4.

In addition, the converting unit 110 used in the hall sensor according to the embodiment of the present invention may further include first and second buffers B1 and B2, a logical gate XOR, and an output buffer OBUF.

The first and second buffers B1 and B2 may buffer output signals of the first and second transistors MN3 and MN4, respectively, the logical gate XOR may perform an exclusive OR operation on outputs of the first and second buffers B1 and B2, and the output buffer OBUF may buffer an output of the logical gate XOR.

Each of the first and second inverters I1 and I2 may be configured by stacking PMOS transistors MP1 and MP2 and NMOS transistors MN1 and MN2 and be formed between a driving power supply terminal VDD and a ground.

First, the first and second detection voltages V_{Houtp} and V_{Houtn} are respectively input to gates of the first and second transistors MN3 and MN4, and a preset reference clock Clk_detection is input to each of the first and second inverters I1 and I2. When a signal exists in the reference clock (Clk_detection), it is level-inverted by the first and second inverters I1 and I2, and the first and second transistors MN3 and MN 4 are operated like a variable resistor controlled by a gate voltage thereof, such that resistor capacitor (RC) delay is generated. Therefore, an output V_{A} of the first buffer B1 and an output V_{B} of the second buffer B2 may be delayed by a predetermined time and be inverted in a signal level, and the output buffer OBUF may output a signal Pout having a time difference Tₚ between a delay time Tp1 of the output V_{A} of the first buffer B1 and a delay time Tp2 of the output V_{B} of the second buffer B2, which corresponds to the offset, to the counter 130.

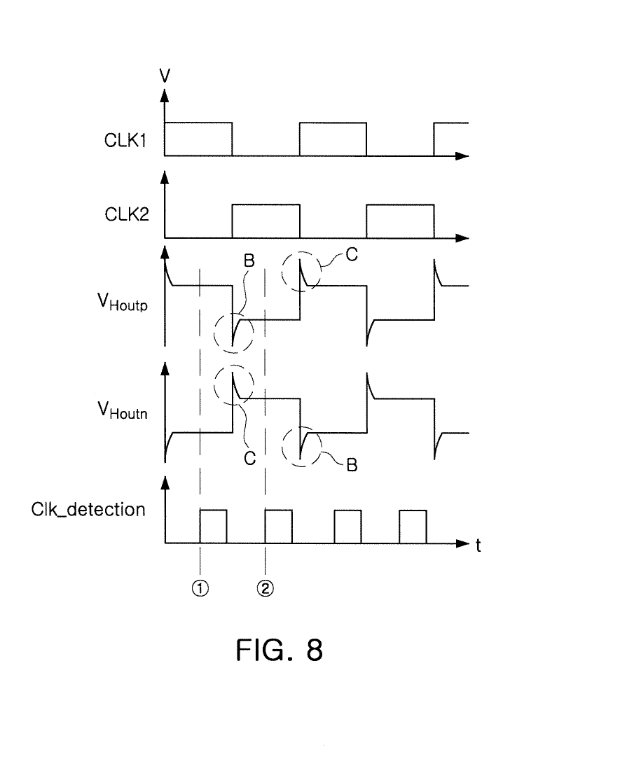

FIG. 7 is a schematic configuration diagram of a sign determining unit used in a hall sensor according to an embodiment of the present invention, and FIG. 8 is signal waveform graphs of main components of a converting unit according to an embodiment of the present invention.

Referring to FIG. 7, the sign determining unit 120 used in the hall sensor according to the embodiment of the present invention may include first and second AND gates AND1 and AND 2 and first and second NOT gates NOT1 and NOT 2. The first and second NOT gates NOT1 and NOT2 may invert levels of outputs of the second and first buffers B2 and B1, respectively, the first AND gate AND1 may perform logical product operation on an output of the first buffer B1 and an output of the first NOT gate NOT1, and the second AND gate AND2 may perform a logical product operation on an output of the second buffer B2 and an output of the second NOT gate NOT2 to thereby determine a sign of a pulse output from the converting unit 110. That is, when a voltage level of the first detection voltage VHₒᵤₜₚ is higher than that of the second detection voltage VHₒᵤₜₙ, it is determined that the pulse has a positive sign, such that a sign determining pulse may be output from a positive sign output terminal Ps+, and when the voltage level of the first detection voltage VHₒᵤₜₚ is lower than that of the second detection voltage VHₒᵤₜₙ, it is determined that the pulse has a negative sign, such that the sign determining pulse may be output from a negative sign output terminal Ps−. The above-mentioned sign determining pulse is transferred to the operating unit 140.

Referring to FIG. 1, the counter 130 may count the width of the pulse from the converting unit 110 with a preset reference time unit. That is, the counter 130 may count the width of the pulse in the reference time unit in a time to digital converter scheme. More specifically, the counter may count the number of the width of the pulse from the converting unit 110 while repeatedly reducing the width thereof in the reference time unit. For example, when the width of the pulse from the converting unit 110 is repeatedly counted three times in the reference time unit, if the width of the pulse does not remain or is smaller than the reference time unit, the number by which the width of the pulse is counted may be regarded as 3. Likewise, when the width of the pulse from the converting unit 110 is repeatedly counted seven times in the reference time unit, if the width of the pulse does not remain or is smaller than the reference time unit, the number by which the width of the pulse is counted may be regarded as 7.

The number of the width of the pulse counted by the counter 130 may be transferred together with the sign of the pulse to the operating unit 140.

The operating unit 140 may include the first and second storing units 141 and 142 and the subtracting unit 143. Each of the first and second storing units 141 and 142 may store the number and the sign therein, the number and the sign corresponding to the pulse according to a level difference between the first and second detection signals for each of the vertical and horizontal directions, which are detection directions of the hall device A, and the subtracting unit 143 may perform a minus operation on the numbers stored in the first and second storing units 141 and 142. Therefore, the offset voltage included in the first and second detection signals may be removed and only a voltage twice larger than the hall voltage may be found.

TABLE 1

| | | | | Voltage |
|---|---|---|---|---|
| | | | | Twice |
| | | | | Larger Than |
| | +10 (Hall | −10 (Hall | Minus | Hall |
| | Voltage) | Voltage) | Operation | Voltage |
| +13 (Offset | 23 | 3 | 23 − 3 | 20 |
| Voltage) | | | | |
| +2 (Offset | 12 | −8 | 12 + 8 | 20 |
| Voltage) | | | | |
| −13 (Offset | −3 | −23 | −3 + 23 | 20 |
| Voltage) | | | | |

For example, it may be appreciated that when it is assumed that an operation is performed on the hall voltage and the offset voltage as represented by Table 1, although the offset voltage is biased to a plus voltage level or a minus voltage level or is slightly generated to have a voltage level value in the vicinity of ‘0’, the offset is accurately removed.

Meanwhile, referring to FIG. 5, the converting unit 110 may have an offset voltage V_{MPCOS} generated due to parasitic components and errors in design through transistors, or the like. The offset voltage V_{MPCOS} may also be expressed as a direct current voltage. Therefore, the total offset voltage may become the sum between the offset voltage V_{OS} of the hall device A and the offset voltage V_{MPCOS} of the converting unit 110. Referring to FIG. 8, when there is no offset voltage, a pulse measured at a point in time of a recognition sign \textcircled{1} may be the same as a pulse measured at a point in time of a recognition sign \textcircled{2} in the case in which the input signals thereof are the same. However, when the offset occurs, a width of the pulse measured at a point in time of the recognition sign \textcircled{1} may be different from that of the pulse measured at a point in time of the recognition sign \textcircled{2}.

In addition, since there are residual spike voltages in edges of the first and second clock signals CLK1 and CLK2 as shown in recognition signs B and C, the reference clock Clk_detection should not be overlapped with the edges of the first and second clock signals CLK1 and CLK2.

As set forth above, according to the embodiments of the present invention, the offset included in the hall voltage is removed by converting the hall voltages into the pulses, counting the converted pulses, and performing the minus operation on the counted numbers, whereby the hall sensor in the digital scheme in which a circuit is easily implemented, power consumption is low, and the offset of the output signal is removed may be provided.

While the present invention has been shown and described in connection with the embodiments, it will be apparent to those skilled in the art that modifications and variations can be made without departing from the spirit and scope of the invention as defined by the appended claims.

What is claimed is:

1. A hall sensor having an offset removal function, comprising:
a converting unit converting first and second detection voltages detected for each of a plurality of preset detection directions by a hall device detecting a magnetic field as a voltage according to the plurality of preset detection directions into a pulse having a level difference therebetween as a width;
a sign determining unit comparing the first and second detection voltages with each other and determining whether the pulse has a positive sign or a negative sign according to the comparison result;
a counter counting the width of the pulse from the converting unit with a preset reference time unit; and
an operating unit removing an offset voltage included in the first and second detection voltages by performing a minus operation with the numbers counted by the counter according to the sign determined by the sign determining unit.

2. The hall sensor of claim 1, wherein the converting unit includes:
first and second inverters connected between a driving power supply terminal and a ground to thereby perform respective inverting operations according to a preset reference clock signal;
a first transistor connected between the first inverter and the ground to thereby receive the first detection voltage through a gate thereof;
a second transistor connected between the second inverter and the ground to thereby receive the second detection voltage through a gate thereof; and
a logical gate performing an exclusive OR operation on outputs of the first and second transistors.

3. The hall sensor of claim 2, wherein the converting unit further includes:
a first buffer buffering the output of the first transistor and transferring the buffered output to the logical gate; and
a second buffer buffering the output of the second transistor and transferring the buffered output to the logical gate.

4. The hall sensor of claim 3, wherein the converting unit further includes an output buffer buffering an output of the logical gate.

5. The hall sensor of claim 2, wherein the sign determining unit determines the positive sign or the negative sign of the pulse by comparing the output of the first transistor with the output of the second transistor.

6. The hall sensor of claim 5, wherein the sign determining unit includes:
a first NOT gate inverting the output of the second transistor;
a first AND gate performing a logical product operation on the output of the first transistor and the output of the second transistor inverted from the first NOT gate;
a second NOT gate inverting the output of the first transistor; and
a second AND gate performing the logical product operation on the output of the first transistor inverted from the second NOT gate and the output of the second transistor.

7. The hall sensor of claim 1, wherein the operating unit includes:
a first storing unit storing the number corresponding to the first detection voltage from the counter therein;
a second storing unit storing the number corresponding to the second detection voltage from the counter therein; and
a subtracting unit performing the minus operation on the numbers stored in the first and second storing units.

8. The hall sensor of claim 1, wherein the counter counts the width of the pulse in the reference time unit in a time to digital converter scheme.

9. The hall sensor of claim 1, wherein the detection directions are a vertical direction and a horizontal direction with regard to a hall plate of the hall device.

10. The hall sensor of claim 9, wherein the operating unit performs the minus operation on the number of pulses counted when the detection direction is the vertical direction and the number of pulses counted when the detection direction is the horizontal direction.

11. An offset removing method of a hall sensor comprising:
converting first and second detection voltages detected for each of a plurality of preset detection directions by a hall device detecting a magnetic field as a voltage according to the plurality of preset detection directions into a pulse having a level difference therebetween as a width;
comparing the first and second detection voltages with each other and determining whether the pulse has a positive sign or a negative sign according to the comparison result;
counting the width of the pulse with a preset reference time unit; and
removing an offset voltage included in the first and second detection voltages by performing a minus operation on the counted numbers according to the determined sign.

12. The offset removing method of claim 11, wherein the converting includes:
inverting the first and second detection voltages according to a preset reference clock signal; and
performing an exclusive OR operation on the inverted voltages.

13. The offset removing method of claim 12, wherein the converting further includes buffering the inverted voltages before performing the exclusive OR operation on the inverted voltages.

14. The offset removing method of claim 12, wherein the converting further includes buffering a result of the exclusive OR operation.

15. The offset removing method of claim 12, wherein the determining includes determining whether the pulse has the positive sign or the negative sign by comparing the inverted voltages with each other.

16. The offset removing method of claim 15, wherein the determining includes:
inverting the inverted voltages respectively;
performing a logical product operation on the inverted voltage of the first detection voltage and the inverted voltage of the inverted voltage of the second detection voltage; and
performing the logical product operation on the inverted voltage of the second detection voltage and the inverted voltage of the inverted voltage of the first detection voltage.

17. The offset removing method of claim 11, wherein the removing of the offset voltage includes:
storing the counted numbers corresponding to the first and second detection voltages; and
performing the minus operation on the counted numbers corresponding to the stored first and second detection voltages.

18. The offset removing method of claim 11, wherein the counting includes counting the width of the pulse in the reference time unit in a time to digital converter scheme.

19. The offset removing method of claim 11, wherein the detection directions are a vertical direction and a horizontal direction with regard to a hall plate of the hall device.

20. The offset removing method of claim 19, wherein the counting includes performing the minus operation on the number of pulses counted when the detection direction is the vertical direction and the number of pulses counted when the detection direction is the horizontal direction.
